(19) United States
(12) Patent Application Publication
(10) Pub. No.: US 2006/0197228 A1
(43) Pub. Date: Sep. 7, 2006

(54) SINGLE MASK PROCESS FOR VARIABLE THICKNESS DUAL DAMASCENE STRUCTURES, OTHER GREY-MASKING PROCESSES, AND STRUCTURES MADE USING GREY-MASKING

(75) Inventors: Timothy Harrison Daubenspeck, Colchester, VT (US); Jeffrey Peter Gambino, Westford, VT (US); Kevin Allen Ostrowski, Burlington, VT (US); Wolfgang Sauter, Richmond, VT (US)

Correspondence Address: WHITHAM, CURTIS & CHRISTOFFERSON, P.C., 11491 SUNSET HILLS ROAD, SUITE 340, RESTON, VA, 20190, US

(73) Assignee: INTERNATIONAL BUSINESS MACHINES CORPORATION, Armonk, NY (US)

(21) Appl. No.: 10/906,752

(22) Filed: Mar. 4, 2005

(51) Int. Cl. H01L 23/48

(52) U.S. Cl. 257/773

(57) ABSTRACT

By using a multiple grey tone mask with at least two greys in semiconductor manufacture, multiple wiring thicknesses can now be made in a single level where previously only one wiring thickness could be provided. For example, power and signal wires of different thicknesses in a single layer can be provided.

### BACKGROUND OF THE INVENTION

1. Field of the Invention

The present invention generally relates to semiconductor device manufacturing.

2. Background

Certain dual damascene structures are known. For example, U.S. Pat. No. 5,795,823 discloses a dual damascene structure. U.S. Pat. No. 6,436,587 discloses forming a dual damascene structure (lines and vias) using a single optical phase shift mask.

An example of a prior art damascene process, U.S. Pat. No. 6,355,399, is a single mask dual damascene process using a dual tone mask. In a starting material, a metal level underlies a dielectric, and a dielectric underlies the metal. Usually the dielectric layer (such as silicon dioxide, fluorine doped silicon dioxide, carbon doped silicon dioxide, etc.) has a low dielectric constant of 4.2 or less. Photoresist is applied on the top dielectric layer. In the next step, the photoresist is exposed through the dual tone mask (which includes opaque regions with no (0%) light transmission, clear regions with full (100%) light transmission, and partially transparent regions with partial light transmission (greater than 0% but less than 100%). In a next step, the resist is developed; in some regions (where vias will be formed) the resist is completely developed and in other regions (where trenches will be formed) only some of the resist is removed, depending on which area of the dual tone mask lies above the resist. The resist profile is then transferred into the dielectric using RIE. Thus concludes a prior art single mask dual damascene process using a dual tone mask. There are limitations in what structure can be constructed according to such processes.

For copper back end of the line (BEOL) dual damascene structures, two masks and lithography processes have been needed to print vias and wiring separately. Cost as well as tool time has been significantly affected by the need for two separate masks and lithography processes. Also, as conventional processes are conducted, a wiring level may only have one given thickness that is constant across the entire wafer, not multiple thicknesses.

Published U.S. Patent Application No. 20030062627 dated Apr. 3, 2003 discloses a damascene structure, and a method of fabricating it, that uses a silicon-based, photoresist material (e.g., plasma polymerized methylsilane (PPMS)) as an etch-stop, hard mask or resist, to form a dual or single damascene structure. The PPMS is patterned using ultra-violet (UV) light in conjunction with either an opaque mask or a grey tone mask.

U.S. Pat. No. 6,355,399 discloses a method for the creation of a dual damascene structure, in which a grey tone mask is used to form dual damascene trenches in one single masking and etch step. The grey tone mask technology allows for a photoresist patterning process after which the photoresist profile can be transferred into the underlying substrate by an etch process. By making the photoresist profile equal to the profile of a dual damascene structure, the dual damascene profile can be created in the surface of a substrate.

U.S. Pat. No. 6,767,673 discloses the use of grey-tone masks where light passes through the photomask in a graded manner. Light passing characteristics of the grey-tone mask can be adjusted so that not only complete passing or complete blocking of light takes place but so that the mask provides a graded exposure that may for instance be of use in creating dual damascene structures, where depth of light exposure can be used for non-uniform removal of a layer of photo-resist over the thickness of the layer of photoresist.

Pierre Sixt, “Phase Masks and Gary-Tone Masks,” Semiconductor FabTech, 1995, pages 209-213, discloses grey-tone masks, formed from repetitive patterns of dots that appear as transparent holes on the chromium mask of the reticle, used to form multi-level resist profiles.

Two wiring thicknesses on one metal layer have been implemented in certain structures. In this approach, the thick wire was formed using the via mask (via bars) and the thin wire was formed using the trench mask, see, e.g., R. F. Schnabel, G. Bronner, L. Clevenger, D. Dobuzinsky, G. Costrini, R. Filippi, J. Gambino, M. Hug, R. Iggulden, C. Lin, K. P. Muller, G. Mueller, J. Nuetzel, C. Radnes, S. Weber, F. Zach, “Slotted vias for dual damascene interconnects in 1 Gb DRAMs,” 1999 Symposium on VLSI Technology Digest of Technical Papers, pages 43-44. However, in other structures, two wiring thicknesses may have been wanted but there has not conventionally been practical technology for producing such desirable features.

### SUMMARY OF THE INVENTION

The present inventors have recognized that the above-mentioned problems may be addressed by grey tone masking. Using a grey tone mask, it is now possible to achieve at least two novel and advantageous results. First, a full dual damascene process can be done with one single mask and lithography step. Second, wiring structures can be created of different thicknesses. Such different size wires can be very efficient in reducing voltage drop on global wires while minimizing cross-talk on smaller signal lines. In addition, trenches for arrays of wires can be etched deeper than trenches for isolated wires, to compensate for CMP dishing, thereby achieving the same final wire thickness and reducing line-to-line variation in resistance in the array.

In the invention, advantageously, by masking with multiple (i.e., two or more than two) grey tones in the mask, novel structures may be produced by gate conductor patterning and contacts patterning, such as structures with two or more different gate conductor thicknesses and structures with two or more different contact depths, or two or more trench isolation depths.

In one preferred embodiment, the invention provides a method of forming a planarized structure, comprising: (a) applying a multiple grey tone mask having at least two grey tones wherein a pattern of trenches and vias with varying depths and thicknesses are formed; (b) simultaneously filling the trenches and vias with a conductive material, wherein the planarized structure that is formed has at least one selected from the group consisting of: a pattern of trenches and vias with varying depths and thicknesses, wires of different thicknesses, gate conductors of different thicknesses, different contact heights, or isolation trenches of different thicknesses. Examples of such inventive methods include, without the invention being limited to such examples, e.g., methods wherein the multiple grey tone mask is applied to pattern one selected from the group consisting of: a dielectric; a conductor; and a semiconductor; methods including after the step (b), a step (c) of removal of excess metal; methods wherein the removal of excess metal is by chemical-mechanical polishing (CMP) or electrochemical mechanical polishing (ECMP); methods wherein the multiple grey tone mask is the only mask used in forming the planarized structure; methods wherein the planarized structure formed is a copper BEOL dual damascene structure (such as, e.g., methods wherein the copper BEOL dual damascene structure is formed with no more than one mask and no more than one lithography process, and wherein vias and wiring are not printed separately); methods including a via-first dual damascene process, wherein two masks are used, and the structure formed has variable wire thickness; methods including forming trenches for signal wiring and power wiring from a same via-forming mask; methods wherein the trenches formed are selected from the group consisting of: wiring trenches; isolation trenches; and gate conductor trenches; methods including a step of subtractive etching to pattern wire with multiple wire thicknesses; etc.

In another preferred embodiment, the invention provides a semiconductor device comprising a planarized structure having a pattern of trenches and vias with varying depths and thicknesses, such as, e.g., a semiconductor device which is a copper BEOL dual damascene structure; a semiconductor device in which in a single layer, power lines vary from signal lines as to depth or thickness; a semiconductor device wherein the trenches and vias are metal-filled, and the device includes power wiring and signal wiring with the power wiring and the signal wiring of different thicknesses from each other; a semiconductor device wherein the trenches are wiring trenches; a semiconductor device wherein the trenches are isolation trenches; a semiconductor device including a bipolar CMOS chip in a single wafer; etc.

The invention also provides a preferred embodiment which is a multiple grey tone mask using multiple layers of MoSi separated by SiO₂ to form regions with different amounts of light transmission.

### BRIEF DESCRIPTION OF THE DRAWINGS

The foregoing and other objects, aspects and advantages will be better understood from the following detailed description of a preferred embodiment of the invention with reference to the drawings, in which:

FIGS. 1A-E show dual damascene processing according to an embodiment of the invention, with multiple trench depths using one mask for vias, with multiple thickness trenches being formed.

FIGS. 2A-E show dual damascene processing according to another inventive embodiment, with multiple trench depths using a single mask.

FIGS. 3A-F show an inventive embodiment which is a single mask process for making multiple isolation trench depths.

FIGS. 4A-E show an inventive process for constructing aluminum wiring with different thicknesses for BEOL wiring and resistor.

FIGS. 5 and 6 are detailed views of embodiments of FIG. 2A. FIG. 5 depicts exposure through a multilayer dual tone mask. FIG. 6 depicts exposure through a pixellated dual tone mask.

### DETAILED DESCRIPTION OF A PREFERRED

### EMBODIMENT OF THE INVENTION

The invention makes use of a grey tone mask that allows different amounts of light to penetrate through the mask in different regions, specifically, a mask providing “multiple” grey tones (referred to herein as a “multiple grey tone mask”). “Multiple” herein refers to two or more than two.

On a positive acting resist, the resist would be removed where hit by light and would remain where blocked out. In grey areas of the mask, different amounts of light would be transmitted, depending on the design of the mask; for example, some grey-tone regions might transmit 30% of the light whereas other grey-tone regions might transmit 50% of the light.

General principles of grey tone masks with a single grey-tone have been previously articulated, such as in previous work with photosensitive polyimides (PSPI). The present invention extends masking technology to use a range of grey tones in the same mask, such as, e.g., two grey tones in the same mask; three grey tones in the same mask; etc.

One embodiment of the invention provides certain dual damascene processing in devices including power wiring and signal wiring. The performance specifications for power wiring and signal wiring differ, and the optimum thickness for each correspondingly differs. In the case of signal wires, usually thinner wires are preferred to reduce line to line capacitance, which otherwise interferes with the signal. By contrast, for power wires, as little voltage drop as possible is wanted, because any voltage drop along the power line is detrimental to operation of the device; therefore power wires should be as thick as possible. However, in conventional dual damascene processing, only one thickness of wire can be provided; conventionally power wires would be constructed on one level, and signal wires would be constructed on another level of a semiconductor device made by dual damascene processing.

The present inventors have recognized that it would be desirable to be able to provide varying wire thickness on a single level in dual damascene processing, and have invented dual damascene processing with multiple trench depths in order to provide, in a single level of a semiconductor device, at least two wiring thicknesses, such as at least one power-wire thickness (e.g., a thickness of about 0.2 μm to 25 μm) combined with at least one signal-wire thickness (e.g., a thickness of about 0.1 μm to 5 μm), usually with the power wire being about twice to five times thicker than signal wire.

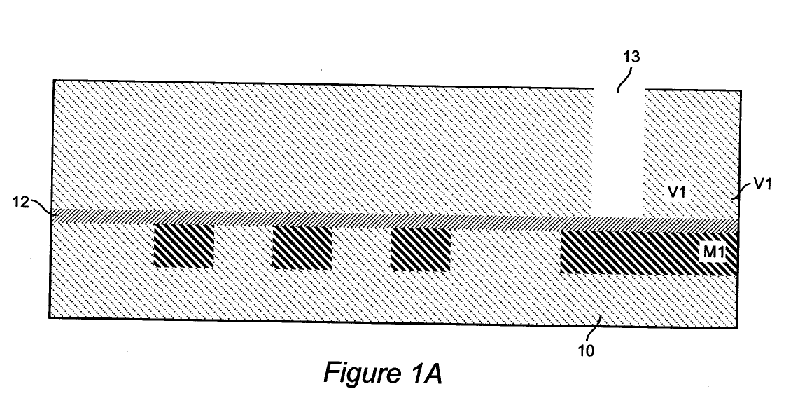

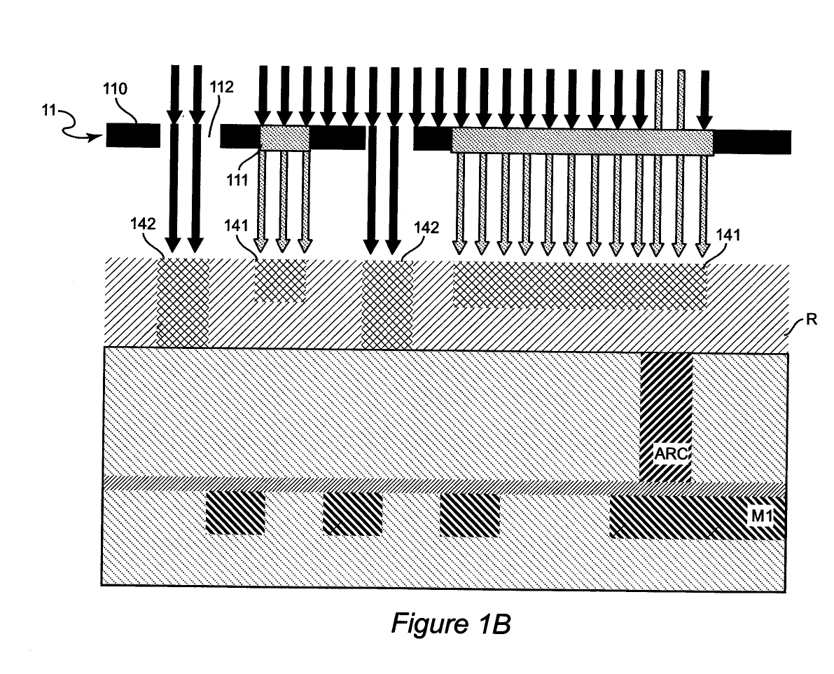

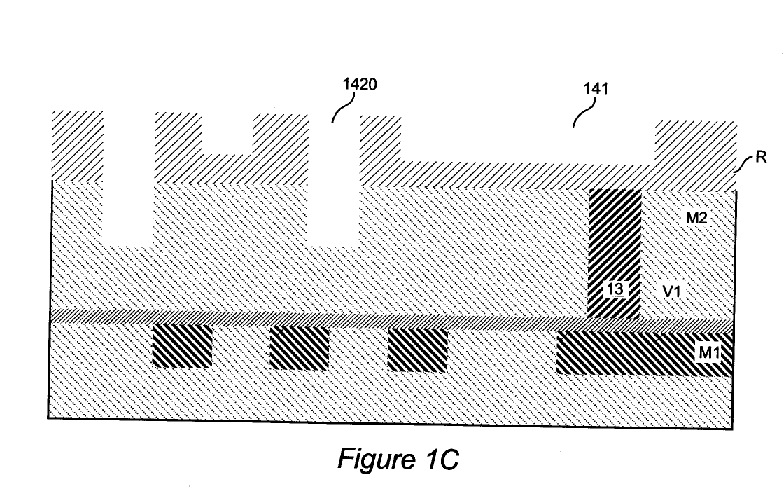

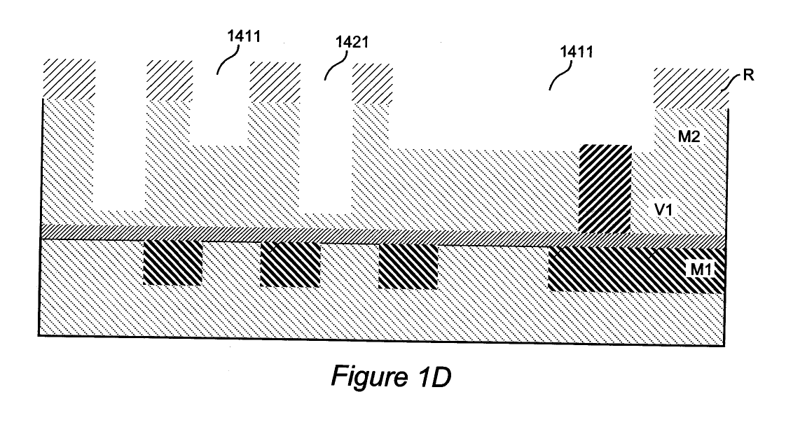

Dual damascene processing with multiple trench depths, according to an embodiment of the invention, is shown in FIGS. 1A-E. In FIG. 1A, via lithography and reactive ion etching (RIE) is shown. A wiring layer M1 (such as, e.g., copper) is embedded in a dielectric 10. An etch stop 12 (such as, e.g., a silicon nitride etch stop) is provided on the M1 layer and the dielectric 10 (such as, e.g., a silicon dioxide dielectric, etc.). A dielectric layer is provided on the V1 layer where trenches and vias are to be constructed. In FIG. 1A, via 13 has been patterned in the V1 layer. As an example, a V1 layer may be SiO₂.

The product under construction shown in FIG. 1A is further processed as shown in FIG. 1B. An antireflective coating (ARC) is applied to the wafer as the first step in the lithography process, to minimize reflections and to protect the bottom of the via during the trench etch. A photoresist R is applied on top of the ARC. FIG. 1B shows the resulting developed pattern corresponding to exposure through the dual tone mask 11. In FIG. 1B, the vertical arrows pointing downwards represent light. The dual tone mask 11 includes mask regions 110 through which no light is transmitted, mask regions 112 through which light is fully transmitted, and mask regions 111 through which light is partially transmitted. Thus, trenches of at least two thickness can be made with a grey tone mask, as can be seen in FIG. 1B where the resist layer R has shallow trenches 141 and deep trenches 142.

The product shown in FIG. 1B is further processed by partial deep trench reactive ion etching. The deep trenches 142 are partially etched into the dielectric underneath (such as etching half-way into the dielectric), forming etched deep trenches 1420 (see FIG. 1C). Where shallow trenches 141 are located, resist layer R will still be present over the shallow trenches 141. Note that after the partial etch of the deep trenches, there is no etching of the shallow trenches.

Next, resist is removed from the bottom of the shallow trenches 141 using RIE with O₂, N₂, or H₂-based chemistries, followed by etching of the dielectric in the shallow trenches 1411 (see FIG. 1D). Note that resist remains in regions with no vias or trenches. Resist is removed at the bottom of the shallow trenches 141. Also the remaining depth of deep trenches 1420 is etched by RIE forming etched deep trenches 1421 (see FIG. 1D). Thus, RIE has been used to form both shallow and deep trenches using one lithography mask. Finally, the ARC and remaining resist are removed and the SiN at the bottom of the via is etched.

Subsequently, shallow trenches 1411 and deep trenches 1421 are filled with metal, wherein signal wire 1412 and power wire 1422 are provided as shown in FIG. 1E. In FIG. 1E, the signal wire 1412 and the power wire 1422 are of different thicknesses. After metal deposition, excess metal is removed, such as by, e.g., chemical mechanical polishing (CMP), electro-chemical mechanical polishing (ECMP), etc.

A final product having a structure as shown in FIG. 1E is highly advantageous because of the presence of varying wire thicknesses for signal wiring and power wiring in a single layer.

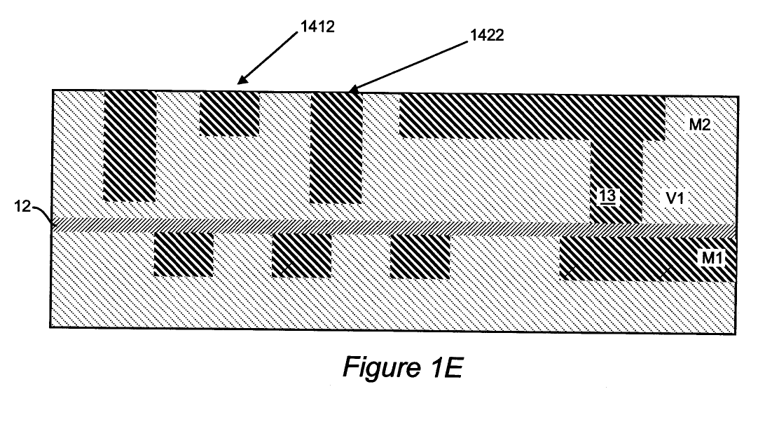

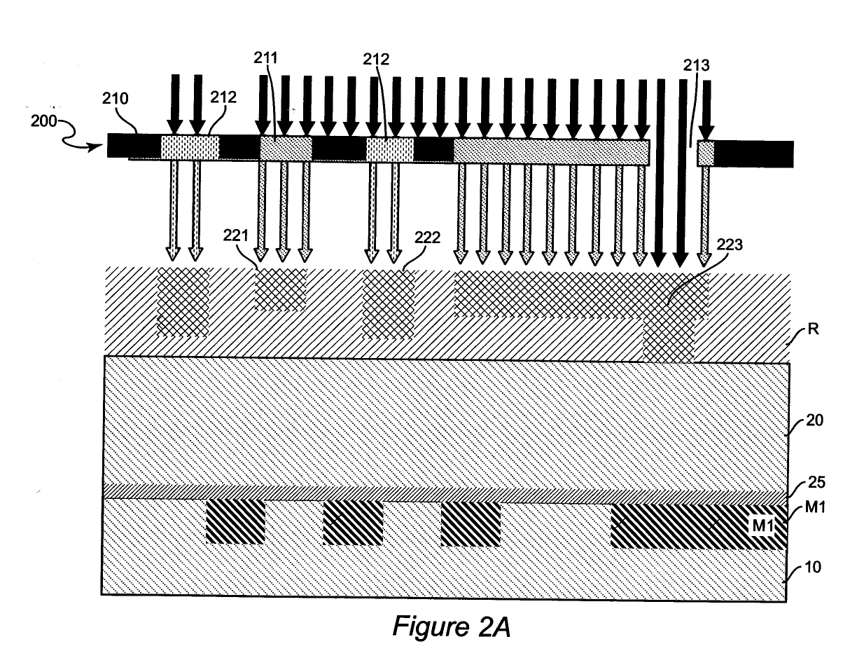

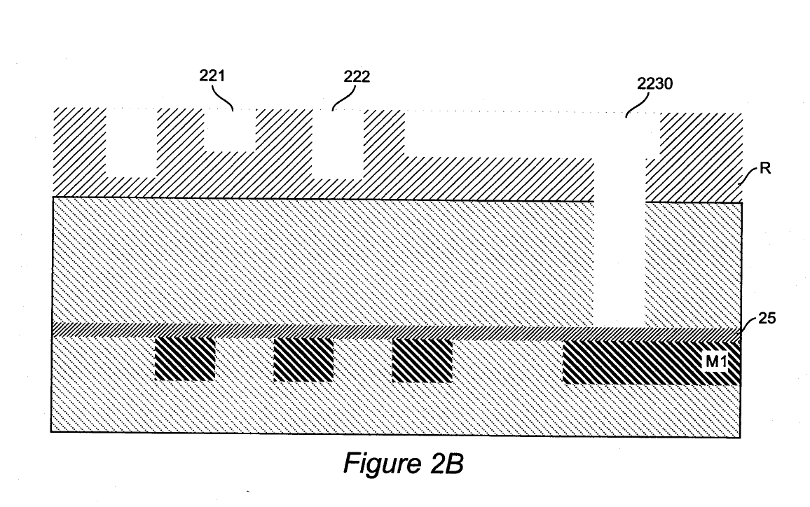

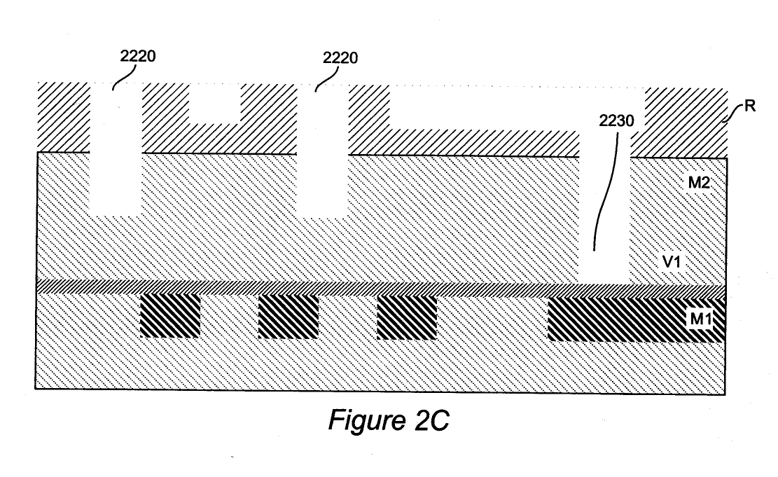

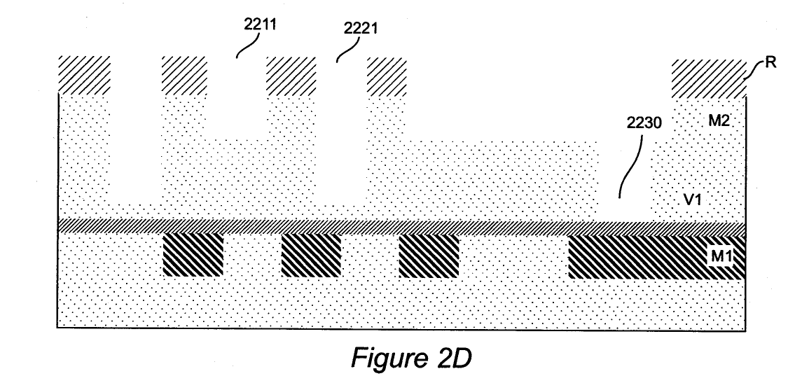

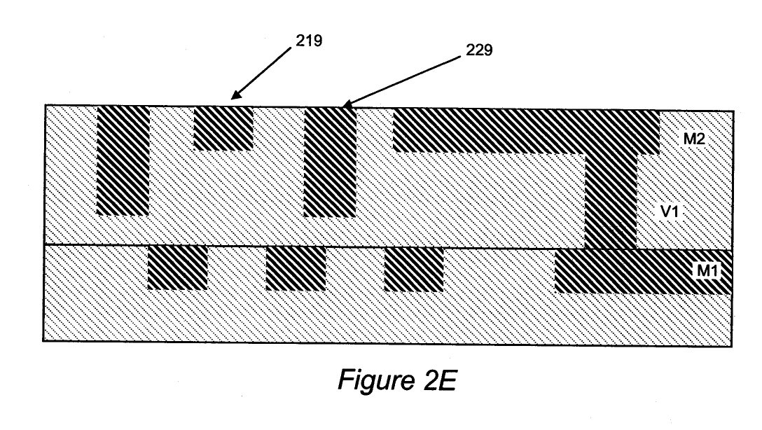

Another inventive embodiment may be appreciated with reference to FIGS. 2A-2E. In FIG. 2A, resist layer R has been provided atop dielectric layer 20 which is atop metal layer M1 and dielectric layer 10. The resist R is exposed through a dual-tone mask 200 which includes mask regions 210 through which no light is transmitted, mask regions 213 through which light is fully transmitted, and grey mask regions 211, 212 through which light is partially transmitted. FIG. 2A shows exposure of the photoresist mask 200.

Grey mask regions 211, 212 differ in the amount of light they permit to pass. That is, the mask 200 is a dual-tone grey mask. For simplicity the mask shown in FIG. 2A has two grey tones, being used to make two trench depths. However, it should be appreciated that a mask having three or more grey tones may be provided, with the number of trench depths to be constructed corresponding to the number of grey tones in the mask.

A first grey tone region in a multiple-grey tone mask is constructed by providing a material of a mask region corresponding to an amount of light desired to pass through that region. A second, different grey tone region in a multiple-grey tone mask is constructed by providing a material of that mask region corresponding to an amount of light desired to pass through that region.

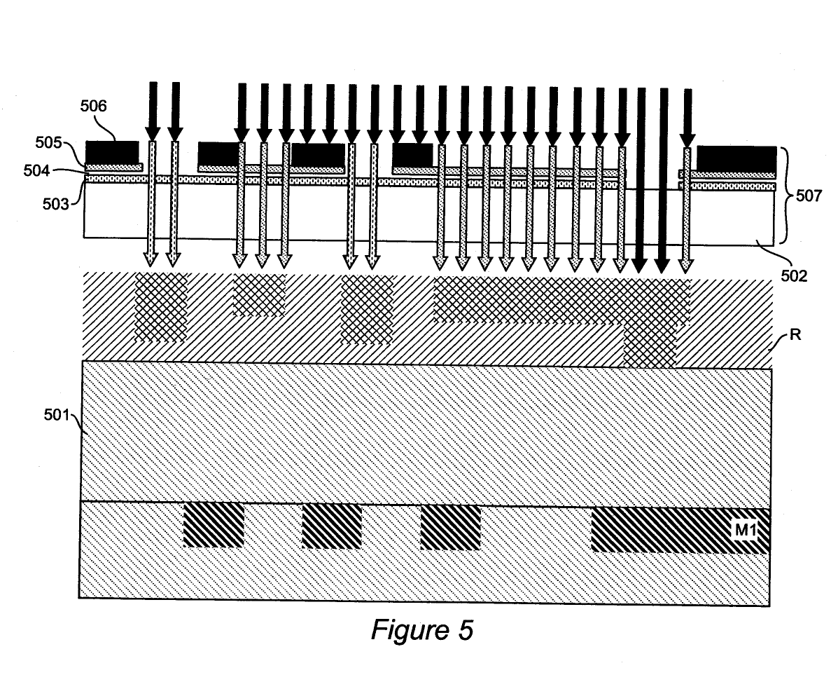

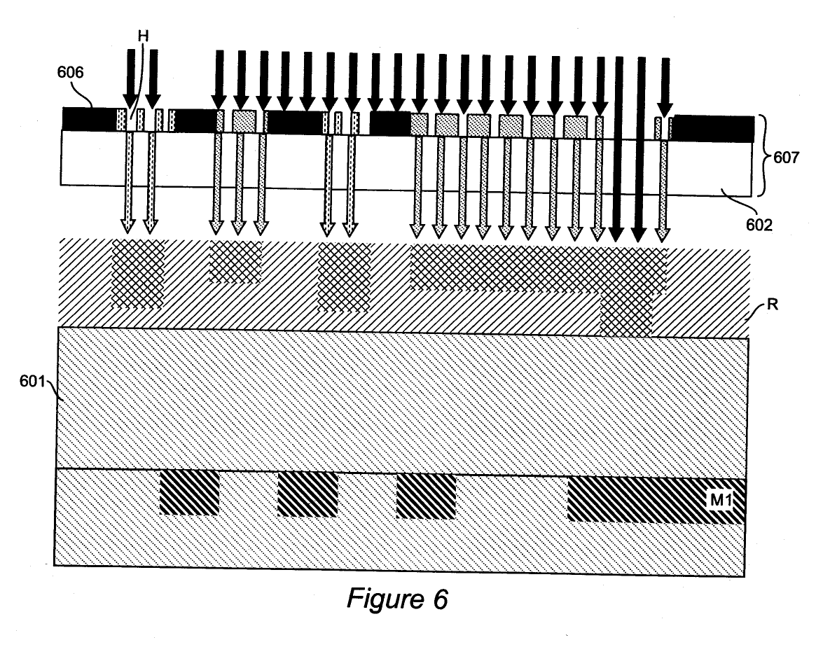

Two examples of grey tone regions are pixellated masks (see, e.g., FIG. 6) and multilayer masks (see, e.g., FIG. 5).

For pixellated masks, an opaque layer of chromium 606 (>100 nm) is deposited on a light transmitting, quartz substrate 602. The chromium is completely removed where full light transmission is required, and is not patterned where zero light transmission is required. However, where partial light transmission is required (i.e., the “grey” regions), “sublithographic” holes H are etched into the chromium. “Sublithographic refers to the size of the hole on the mask with respect to the wavelength of radiation used to expose the photoresist applied to the wafer. For “deep UV” lithography, the wavelength of light is typically 193 or 248 nm, while for “mid-UV” lithography, the wavelength of light is 310 or 450 nm. As an example, if the wavelength of light used to expose the photoresist on the wafer is 450 nm, then the sublithographic holes H in the chromium on the mask should be less than 450 nm, and preferably 400 to 100 nm. The amount of light transmission is determined by the density of sublithographic holes H in the grey regions. A higher density of sublithographic holes H results in more light transmission (but still lower light transmission than in areas with no chromium).

For multilayer masks (such as mask 507 in FIG. 5), two or more layers of light blocking material are used. Typically, a thin layer (50 nm or less) of molybdenum silicide (MoSi) 503 and 505 is used as the partially transmitting layer and a thick layer of chromium (>100 nm) 506 is used as the opaque layer. These are deposited on a light transmitting substrate 502 such as quartz, with chromium 506 deposited on top of the MoSi 505. The chromium is removed from regions where either full or partial light transmission is required. The MoSi is removed where full light transmission is required but remains in regions where partial light transmission is required (i.e. where there is MoSi on top of the glass, but no chromium). To get different amounts of partial light transmission, two or more MoSi layers 505, 503 can be used, with a thin layer of SiO₂ (100 nm or less) 504 in between the layers for an etch stop. One of the MoSi layers can be removed in regions of the mask where a higher intensity of partial light transmission is required.

Returning to FIG. 2A, grey-tone mask region 211 permits an amount of light to pass to pattern trench 221. Grey-tone mask region 212 permits an amount of light to pass to pattern trench 222. Mask region 213 permits all light to pass to make via 223. Note that trenches 221, 222 and via 223 are of three different depths.

The resist R is then developed. Reactive ion etching of the via is performed, stopping on an etch stop 25 (such as a silicon nitride etch stop) (see FIG. 2B). In FIG. 2B, the oxide has been etched with the via etch, providing deep via 2230; the SiO₂ under trench patterns 221 and 222 (FIG. 2B) is not etched during the via etch process.

Subsequently, the resist is partially removed by RIE to expose the ARC in the regions where deep trenches 222 will be formed, followed by RIE to partially etch the deep trenches 2220 (FIG. 2C).

Next, the resist is again partially removed by RIE to expose the ARC in the regions where shallow trenches 221 will be formed (FIG. 2C), followed by RIE to completely etch the shallow trenches 2211 (FIG. 2D) and deep trenches 2221 (FIG. 2D). It will be appreciated that shallow trenches 2211 and deep trenches 2221 have different depths (FIG. 2D).

After the trenches have been formed (FIG. 2D), resist is stripped, SiN is etched from the bottom of the via, followed by filling the trenches with metal (such as copper) to provide signal wires 219 and power wires 229. (FIG. 2E) The signal wires 219 are formed from the shallow trenches and the power wires 229 are formed from the deep trenches. Excess metal is removed, such as by chemo-mechanical polishing (CMP) or electro-chemo-mechanical polishing (ECMP), to provide a final product. Referring to FIGS. 2A-2E, it will be appreciated that the via has been made using the same mask used to form the trenches from which the signal wiring and power wiring was formed.

Above with reference to FIGS. 1A-1E and 2A-2E, making wiring trenches has been discussed. However, it will be appreciated that the invention is not limited to making wiring trenches and that isolation trenches may be made according to the invention.

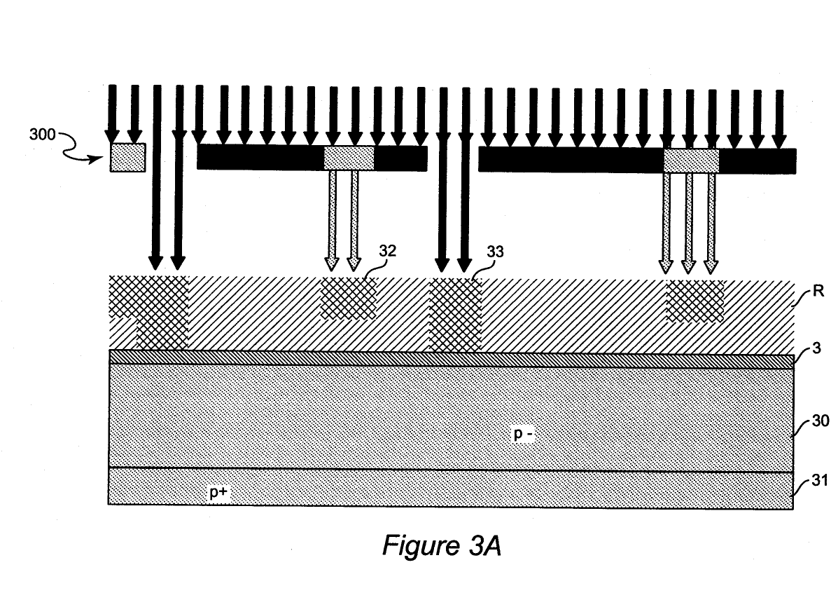

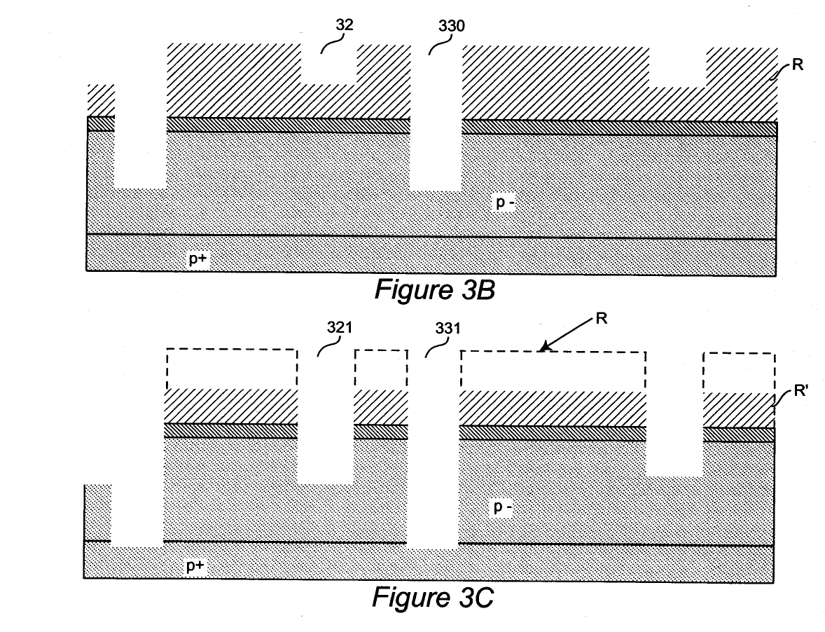

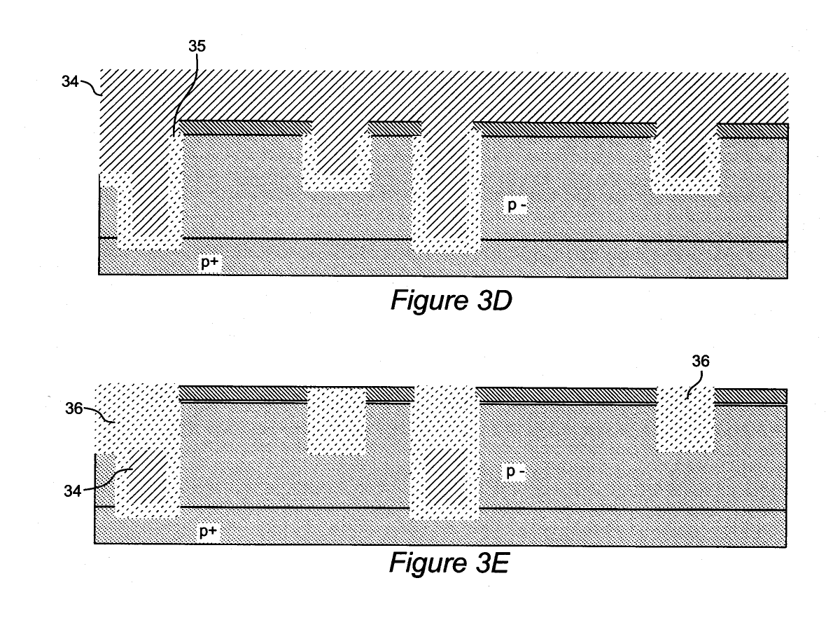

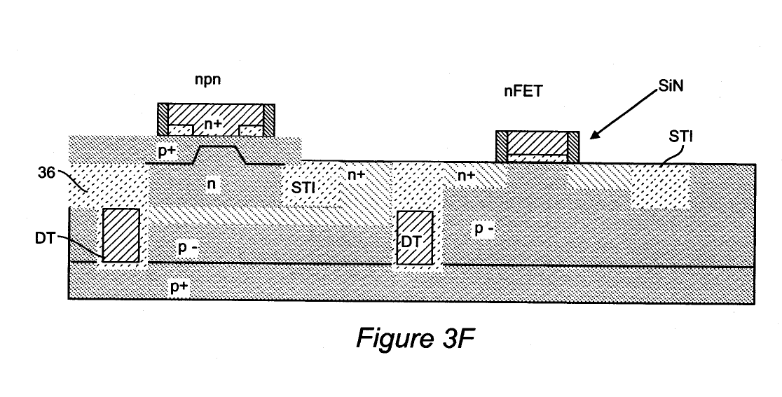

For example, referring to FIG. 3A, a structure is shown that will be used for making isolation trenches. The structure is formed from a silicon water has a resist layer R atop a polish stop layer 3 (such as, e.g., a pad nitride and pad oxide that will serve as a polish stop) that is atop a p-region 30 that is above a p+region 31.

Referring to FIG. 3A, the resist is exposed through a grey tone mask 300 to make shallow trenches 32 and deep trenches 33 in the same step with the same mask 300. Mask 300 includes a single grey tone.

Subsequently a trench etch is conducted (FIG. 3B), to partially etch the deep trench into the silicon to provide etched deep trench 330 (FIG. 3B). The region where shallow trenches 32 will be formed remains unetched.

Next, the resist is partially etched back to remove the resist where the shallow trenches 321 will be formed. (FIG. 3C). When the shallow trench 321 is etched, the deep trench 331 is etched (FIG. 3C). In FIG. 3C, the resist that has been removed by the etch back is shown by dotted lines ( . . . ) and as R and the resist remaining after the etch back is shown as R′.

Next, trench filling is performed (see FIG. 3D). Thermal oxidation is performed to grow silicon dioxide along the sides of trenchs. Polysilicon is deposited over the whole structure. After the trench filling, the structure of FIG. 3D is formed, with poly regions 34 and silicon dioxide region 35.

In subsequent processing, the polysilicon is etched back, silicon dioxide is deposited and silicon dioxide polishing (such as chemical mechanical polishing, etc.) is performed to form the structure of FIG. 3E with silicon dioxide regions 36. The etch back may be, e.g., by reactive ion etching alone or by chemical mechanical polishing combined with reactive ion etching. As a result of this step, polysilicon only remains at the bottom of the deep trenches. In the resulting structure of FIG. 3E, shallow trenches only filled with silicon dioxide are obtained; the deep trenches are filled with silicon dioxide and polysilicon.

Subsequent processing of the structure of FIG. 3E may be conducted according to conventional procedures. For example, the pad oxide and pad nitride are stripped (see FIG. 3F), bipolar transistors and FETs are made (see FIG. 3F), etc. Growth of gate oxides and formation of implants may be done according to conventional processing techniques. Contacts and wiring (not shown in FIG. 3F) may be made. There thus may be fabricated a device as shown in FIG. 3F, which depicts a structure with deep isolation trenches DT and shallow isolation trenches STI. There is thus shown in FIG. 3F a semiconductor device including an npn region (npn) and an nFET device (nFET). There may thus be constructed a bipolar CMOS (BiCMOS) chip in a single wafer. Deep trenches (DT) provide isolation for bipolar transistors. Shallow trenches (STI) provide isolation between FETs.

Although two trench steps have been shown in FIGS. 3A-F for relative simplicity, it should be appreciated that more than two trench steps may be provided, depending on the structure to be manufactured.

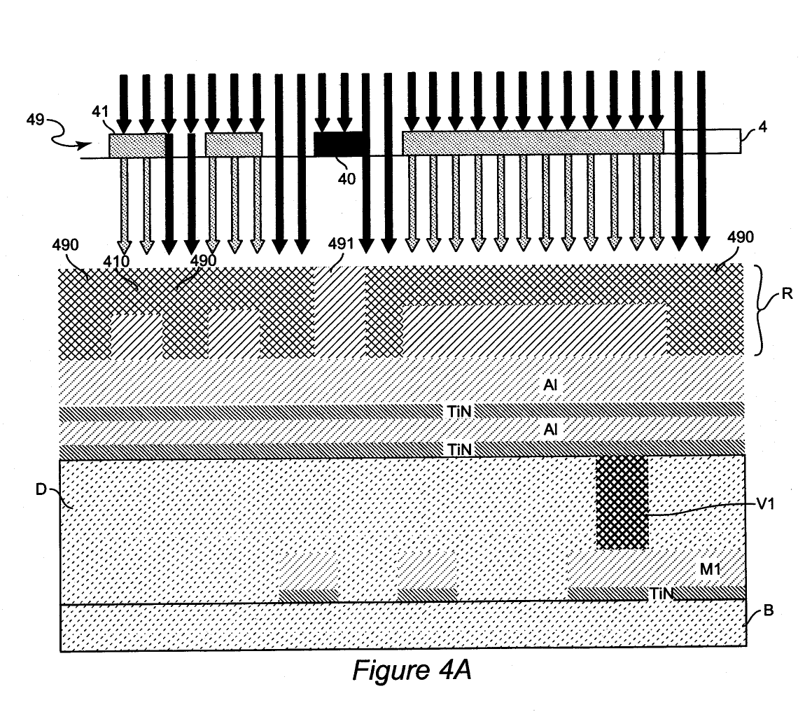

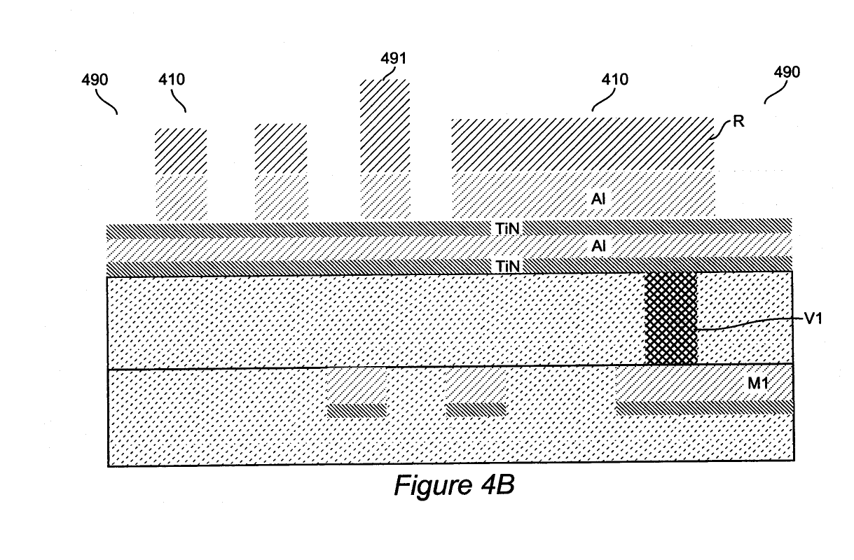

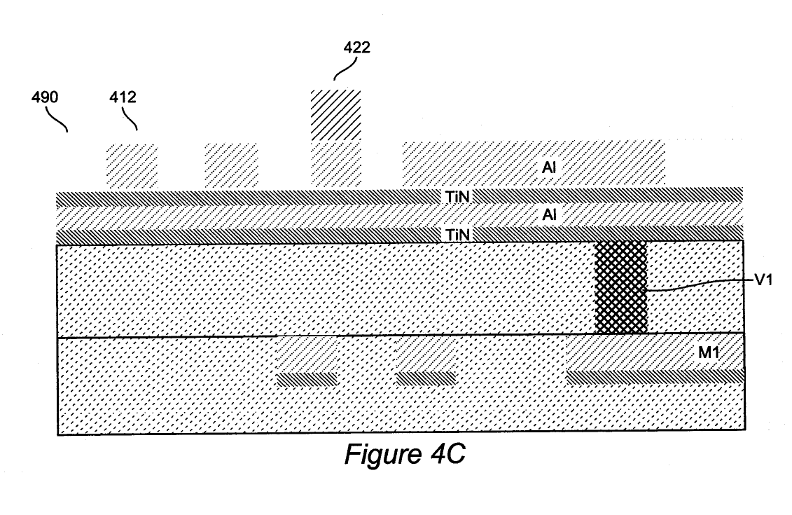

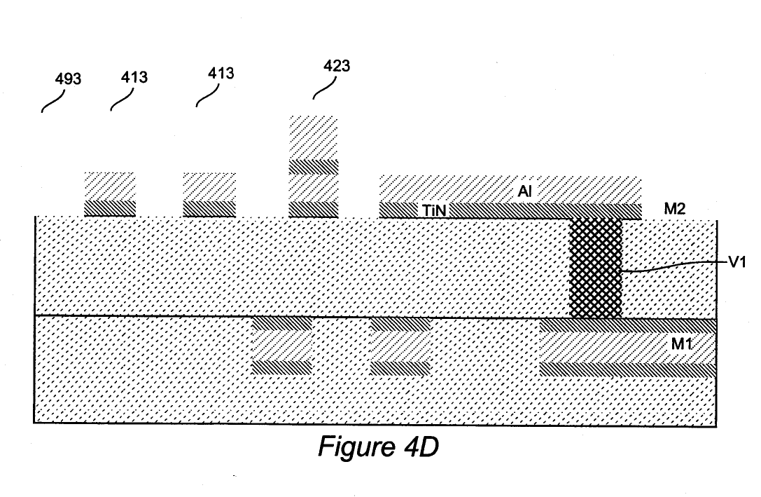

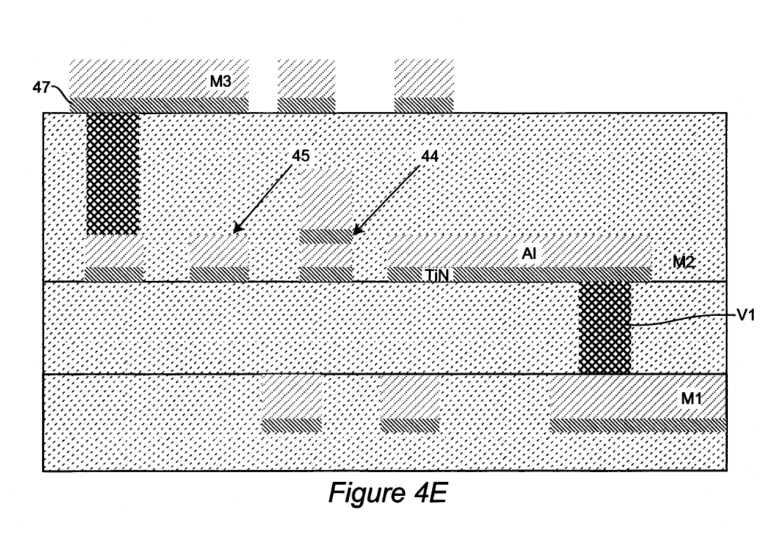

The invention thus may be used for patterning a dielectric or semiconductor, as seen with reference to FIGS. 1A-3F discussed hereinabove. However, the invention also may be used for patterning a conductor. For example, the invention may be used to make semiconductor devices in which aluminum wiring is of different thickness, such as for BEOL wiring and resistors. See FIGS. 4A-E, in which a stack (such as a titanium nitride (TiN)/aluminum (Al)/TiN/Al/TiN stack) is deposited, and exposed through a grey tone mask.

Referring to FIG. 4A, layer TiN is a barrier metal such as titanium, titanium nitride, tungsten, etc. Layer M1 is, e.g., aluminum. Via V1 is, e.g., tungsten wire, etc. Layer B is the BPSG dielectric. Via V1 is provided in a dielectric layer D (such as SiO₂). Those in the art are familiar with M1/V1 structures. An example of TiN and Al stacking is shown in FIG. 4A for illustration. Where a resist layer R had been applied, the resist will be exposed according to a pattern of a mask 40. Resist 491 masked by regions 40 through which no light passes will remain. Resist masked by regions 49 through which all light passes will be completely developed and removed by the exposure step, with full resist removal 490 resulting. Resist masked by a grey tone region 41 will be partly removed, resulting in a thickness of resist 410 that is less than the full thickness.

After the step of exposing the grey tone mask, an etch is performed at the top layer of aluminum, resulting in the etched structure of FIG. 4B. An etch stop such as TiN can be used so that the etch stops there. After the etch, the upper layer of Al has been etched in regions 490 where Al will eventually be completely removed. The full thickness of metal still remains in regions with a partial layer of resist 410 or a full layer of resist, 491. FIG. 4C is formed, wherein regions 490 have partial removal of metal and no resist, regions 412 have full thickness of metal and no resist, and regions 422 have full thickness of metal and some resist.

Subsequently, TiN and Al are etched, to form two different thickness of aluminum wires. It will be noted with respect to FIG. 4D that two different types of material are being etched, which differs from the discussions of FIGS. 1A-3E in which one type of material was being etch. Note that wires 413 and 423 have different thicknesses, and that metal has been completely removed in between the wires 493 (FIG. 4D). Thus subtractive etching (metal RIE) may be used to pattern wiring of different thicknesses.

Referring to FIGS. 4D-4E, the structure of FIG. 4D is further processed, including deposition of another dielectric layer 47 and wiring layer (M3) (such as an M3 layer of aluminum). Power wire 44 and signal wire 45 are provided.

While the invention has been described in terms of its preferred embodiment, those skilled in the art will recognize that the invention can be practiced with modification within the spirit and scope of the appended claims.

1-11. (canceled)

12. A semiconductor device comprising a planarized structure having a pattern of trenches and vias with varying depths and thicknesses.

13. The semiconductor device of claim 12, which is a copper BEOL dual damascene structure.

14. The semiconductor device of claim 12, in which in a single layer, power lines vary from signal lines as to depth or thickness.

15. The semiconductor device of claim 12, wherein the trenches and vias are metal-filled, and the device includes power wiring and signal wiring with the power wiring and the signal wiring of different thicknesses from each other.

16. The semiconductor device of claim 12, wherein the trenches are wiring trenches.

17. The semiconductor device of claim 12, wherein the trenches are isolation trenches.

18. The semiconductor device of claim 12, including a bipolar CMOS chip in a single wafer.

19. A multiple grey tone mask using multiple layers of MoSi separated by SiO₂ to form regions with different amounts of light transmission.
